(19) United States
(12) Patent Application Publication
(10) Pub. No.: US 2009/0302959 A1
(43) Pub. Date: Dec. 10, 2009

(54) SYNCHRONOUS DISTRIBUTED OSCILLATOR

(75) Inventors: Didier Belot, Rives (FR); Thierry Taris, Bordeaux (FR); Jean-Baptiste Begueret, Talence (FR); Yann Deval, Burges (FR); Julie Cassagne, Burges (FR); Herve Lapuyade, Pessac (FR)

Correspondence Address: GARDERE WYNNE SEWELL LLP;INTELLECTUAL PROPERTY SECTION, 3000 THANKSGIVING TOWER, 1601 ELM ST, DALLAS, TX, 75201-4761, US

(73) Assignee: STMicroelectronics S.A., Montrouge (FR)

(21) Appl. No.: 12/478,554

(22) Filed: Jun. 4, 2009

(30) Foreign Application Priority Data
Jun. 6, 2008 (FR) 0853747

(51) Int. Cl. H03B 28/00

(52) U.S. Cl. 331/107 SL

(57) ABSTRACT

A distributed oscillator includes an odd number of serially connected amplifying elements. An output of a last amplifying element is looped back to an input of a first amplifying element via a first transmission line. The oscillator oscillates at a first frequency f1. The oscillator further includes circuitry for injecting a control signal onto the input of the first amplifying element. The control signal has a second frequency f2 which is a sub-multiple of the first frequency f1.

### PRIORITY CLAIM

The present application claims the benefit of French Application for Patent No. 0853747 filed Jun. 6, 2008, the disclosure of which is hereby incorporated by reference.

### TECHNICAL FIELD

The present invention concerns a distributed oscillator comprising a plurality of amplifying elements associated in series, one output of at least one amplifying element being looped back onto an input of a first amplifying element via a first transmission line, the oscillator oscillating at a first frequency.

### BACKGROUND

The fundamental characteristics of an oscillator are its tuning frequency (or oscillation), its power and its frequency stability. The quality of an oscillator is characterized by its phase noise, spectral purity (low harmonics) and range of operating frequency.

Faced with the increase in operating frequencies, the reduced size of integrated circuits and reduced voltage supply of these circuits, designers are confronted with increasingly more difficult fabrication of oscillators having low phase noise, low power consumption and high power output.

Oscillators with a resonant circuit of the LC type show their limits when the operating frequency increases beyond ten or so gigahertz.

Distributed oscillators show a better advantage at higher frequencies: they have high output power and can operate over a wide frequency range.

As an example, FIG. 1a shows a distributed oscillator comprising an uneven number of amplifying elements linked together via sections L of transmission line which act as LC filters. In the example shown in FIG. 1a, the transistors T1, T2, T3 are of the bipolar type. The transistors are commonly mounted in a common emitter configuration: the collectors of all the amplifying elements are linked together by a first group of line sections L1, L2; the bases of all the amplifying elements are linked together via a second group of line sections L3, L4, and the emitters of all the amplifying elements are earthed (grounded).

Each amplifying element amplifies the wave and transfers it towards the output line. End-line reflections are absorbed by the output charge CH. The output of the last amplifying element T3 is linked to the input of the first amplifying element via a link capacitor CL and a first transmission line Lb. Each transmission line section L1, L2, L3, L4 and Lb between two transistor emitters, between two transistor bases, or between the output of the last amplifying element and the input of the first amplifying element is equivalent, from an electric viewpoint, to a distributed LC filter (inductor and capacitor) (cf. FIG. 1b).

Known distributed oscillators have high output power. However, their maximum operating frequency is of the order of ten or so Gigahertz. In addition, known distributed oscillators only oscillate over a single frequency, their natural oscillation frequency; they cannot therefore be used for applications in which the frequency is likely to vary (e.g. for telephony applications).

### SUMMARY

A novel distributed oscillator is presented whose oscillation frequency is able to be varied in relation to a control signal.

Therefore, a distributed oscillator is provided which, similar to a known distributed oscillator, comprises a plurality of amplifying elements associated in series, one output of a last amplifying element being looped back onto an input of a first amplifying element via a first transmission line; the oscillator oscillates at a first frequency.

The oscillator further comprises means to inject a control signal into the input of the first amplifying element, the control signal having a second frequency that is a sub-multiple of the first frequency.

The control signal imposes the oscillation frequency of the oscillator. Therefore, by varying the second frequency (i.e. the control signal frequency), the first frequency is caused to vary (i.e. the oscillation frequency of the distributed oscillator will vary).

The oscillation frequency of the distributed oscillator is, for example, of the order of 2 to 10 times the frequency of the control signal.

Therefore, from a control signal having a second frequency of the order of a few hundred megahertz to a few tens gigahertz, the distributed oscillator oscillates at a first frequency of the order of a few gigahertz to a few hundred gigahertz.

The injection means may, for example, comprise a control circuit of which one output is linked via electromagnetic coupling to the first transmission line.

The control circuit, for example, is a known oscillator of the PLL (Phase Locked Loop) type.

The characteristics (phase noise, locking range, etc.) of the output signal of the oscillator disclosed herein are close to the characteristics of the control signal. Therefore, from a control circuit producing a control signal with low phase noise and having a wide locking range, an oscillator is obtained which has a wide locking range and producing an output signal with low phase noise.

To achieve electromagnetic coupling, the oscillator may, for example, comprise a second transmission line of which one input is connected to the output of the control circuit, and of which one output is connected to a charge. The first transmission line and the second transmission line therefore together form an electromagnetic directional coupler.

In one embodiment of the oscillator, the amplifying elements are fabricated on a silicon substrate and are associated in series firstly via a first group of transmission line sections made in a first metal level located above the substrate, and secondly via a second group of transmission line sections made in a second-to-last metal level located above the first level or in a last metal level positioned above the second-to-last metal level.

The first transmission line and the second transmission line are fabricated in the second-to-last metal level or in the last metal level, the second transmission line being fabricated parallel to the first line. By fabricating the first transmission line and the second transmission line in one same metal level, or in close metal levels, electromagnetic coupling between these two lines is optimized.

The first transmission line and/or the second transmission line may for example be microstrip lines with DGS pattern (Defected Ground Structure). With said lines it is possible to achieve high coupling levels between lines.

The amplifying elements can be distributed on the substrate so that the transmission line sections and the first transmission line are substantially of same length. Therefore transmission lags, generated by the transmission line sections between two amplifying elements, are substantially the same along the entire length of the amplifying chain.

To obtain link sections of substantially same length, it is possible to fabricate an oscillator comprising three amplifying elements distributed in a substantially triangular architecture.

In an embodiment, a circuit comprises an oscillator comprising: a plurality of amplifying elements coupled in series and a first transmission line coupled between an output of a last one of the amplifying elements and an input of a first one of the amplifying elements. The circuit further comprises a control circuit adapted to generate an oscillating control signal and a second transmission line receiving the oscillating control signal from the control circuit at an input and arranged with the first transmission line to form an electromagnetic directional coupler.

In another embodiment, a circuit comprises: a semiconductor substrate; a first transistor, second transistor and third transistor formed on the substrate and positioned at the corners of a triangle; a first transmission line coupled between the first and second transistors; a second transmission line coupled between the second and third transistors; a third transmission line coupled between the third and first transistors; and a fourth transmission line positioned adjacent and parallel to the third transmission line to form with the third transmission line an electromagnetic directional coupler.

### BRIEF DESCRIPTION OF THE DRAWINGS

The invention will be better understood and other characteristics and advantages will become apparent on reading the following description of an example of embodiment of a synchronous oscillator according to the invention. The description is to be read with reference to the appended drawings in which:

FIGS. 1a and 1b are electronic diagrams of a known distributed oscillator,

FIG. 2 is an electronic diagram showing the injection of the second frequency into the distributed oscillator of FIG. 1a, thereby forming a distributed oscillator with injection,

FIG. 3 details the elements of the oscillator shown FIG. 2, and

FIG. 4 shows a variant of embodiment of some elements in FIG. 3.

### DETAILED DESCRIPTION OF THE DRAWINGS

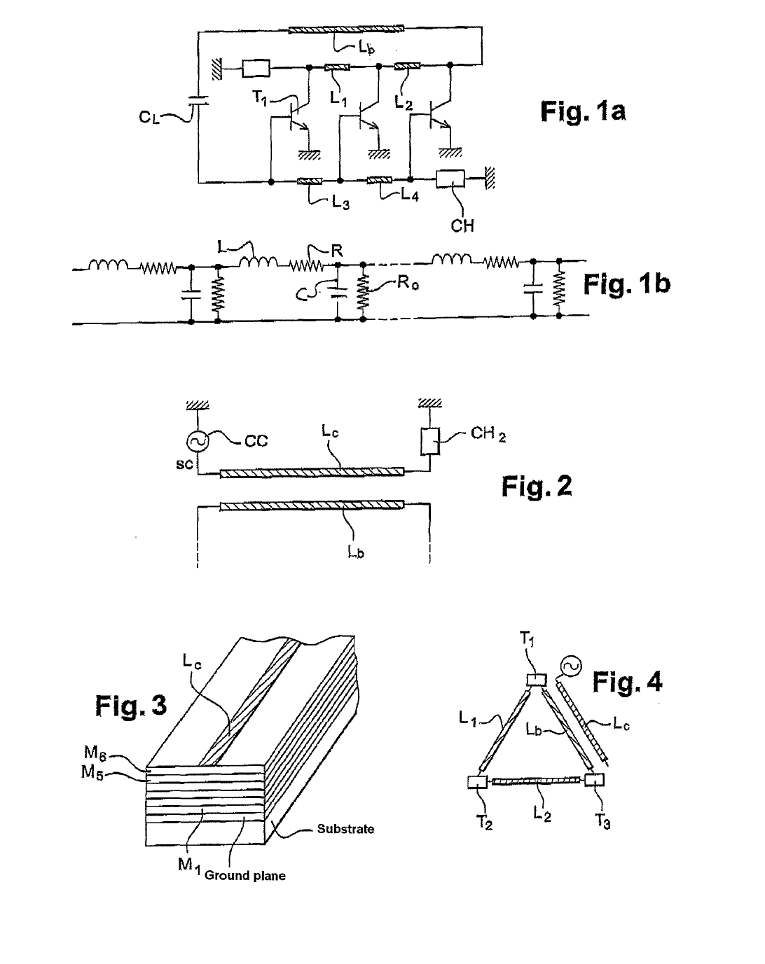

As indicated previously, a distributed oscillator comprises a plurality of amplifying elements T1, T2, T3 associated in series (FIG. 1a), one output of a last amplifying element T3 being looped back onto an input of a first amplifying element T3 via a first transmission line Lb. In the example shown FIG. 1a, a link capacitor CL is added between line Lb and the input of the first amplifying element. This capacitor filters any harmonics which may be present on the output signal of the last amplifying element. The oscillator oscillates at a first frequency f1.

An oscillator according to the invention sets itself apart from known oscillators in that it also comprises means to inject a control signal SC onto the input of the first amplifying element T1, this control signal SC having a second frequency f2 that is a sub-multiple of the first frequency. For example f1=n*f2 may be chosen where n is an integer between 2 and 10.

The injection means is shown in FIG. 2 and comprises a control circuit (CC) of which one output is linked via electromagnetic coupling to the first transmission line Lb of the circuit shown in FIG. 1a. For this purpose, in the example shown FIG. 2, the injection means also comprise a second transmission line Lc of which one input is connected to an output of the control circuit CC, and of which one output is connected to a charge CH2. The first transmission line Lb and the second transmission line Lc are fabricated so that they together form an electromagnetic directional coupler.

The impedance of the charge CH2 is adapted to the impedance of line L2, for example 50 Ohms.

In one example, the control circuit CC is an oscillating circuit of PLL type (Phase Locked Loop) that is frequency-stable.

The amplifying elements T1, T2 and T3 are for example:
bipolar transistors mounted as common emitter (as shown in FIG. 1a), or
MOS transistors having a common source, or
any other known amplifier assembly.

The amplifying elements are preferably connected in series via transmission line sections L1, L2, L3, and L4. In the example shown FIG. 1a, a first group of transmission line sections L1, L2 connects together the collectors of the amplifying elements T1, T2, T3, and a second group of line sections L3, L4 links together the bases of the amplifying elements T1, T2, T3.

The oscillator can be implemented on an integrated circuit, comprising a silicon substrate and a plurality of metal levels positioned above the substrate.

The amplifying elements, the control circuit, the charge or charges, any connecting capacitors, any adaptation elements etc. are fabricated in the silicon and in the metal layers. The first group of line sections L1, L2 can be fabricated in a first metal layer positioned above the substrate and the earth/ground plane, and the second group of line sections can be fabricated in a second metal layer positioned above the first metal layer.

In the example shown FIG. 3, six metal layers are provided. The transmission line Lc is made in the highest metal layer M6; to obtain optimum electromagnetic coupling, the transmission line Lb is made in metal level M5 just underneath metal level M6 in which line Lc is fabricated, and the second line Lc is formed parallel to the first line Lb. The line sections L1, L2 of the first group of line sections are made in metal level M5, and line sections L3, L4 of the second group of line sections are made in metal level MI located just above the substrate.

In known manner, the connections between firstly one end of a transmission line section L1, L2, L3, L4 located in a metal level, and secondly a terminal of a component (amplifying element, capacitor, etc.) of the circuit fabricated on the substrate, are obtained through vertical vias. The same applies to the connections of the ends of transmission lines Lb and Lc.

The first transmission line and/or the second transmission line are conductive microstrip lines e.g. with DGS pattern (Defected Ground Structure).

The amplifying elements are preferably distributed on the substrate so that the transmission line sections and the first transmission line are substantially of same length. This gives substantially the same transmission lags between each amplifying element. Therefore, in FIG. 4, the amplifying elements are distributed on the substrate in a substantially triangular architecture (only sections L1, L2 and the first line Lb can be seen FIG. 4). Transmission line Lc lies parallel to line Lb and is of substantially the same length.

Solely as a non-limiting illustration, an amplifier according to the invention was fabricated on a Si substrate of 10-15 Ohms·cm p type, using BICMOS 0.13 μm technology by STMicroelectronics. The oscillator oscillates at 75 GHz, it is controlled by a control circuit of PLL oscillator type supplying a frequency signal of 25 GHz. Compared with known manufactured oscillators, the oscillator of the invention has characteristics of particular interest:
oscillation frequency (75 GHz) much higher than the frequency of known oscillators (around 5-15 GHz;)
low phase noise, less than −110 dBc/Hz at an offset of 200 kHz from central frequency; in practice the phase noise corresponds to that of the control signal;
considerable improvement in spectral purity (low harmonics in the output signal);
locking range of interest (frequency range over which the oscillator is able to synchronize on a multiple of the control signal frequency), varying between 66 and 96 GHz i.e. 22% of the central oscillating frequency (=75 GHz).

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. A distributed oscillator, comprising:
a plurality of amplifying elements associated in series, one output of a last amplifying element being looped back onto an input of a first amplifying element via a first transmission line, the oscillator oscillating at a first frequency f1; and
means for injecting a control signal into the input of the first amplifying element, this control signal having a second frequency f2 that is a sub-multiple of the first frequency, wherein f1=n*f2;
the means for injecting comprising:
a control circuit having an output that is linked via electromagnetic coupling to the first transmission line; and
a second transmission line of which one input is connected to the output of the control circuit, the first transmission line and the second transmission line together forming an electromagnetic directional coupler.

2. The oscillator according to claim 1, wherein the amplifying elements are connected in series via transmission line sections.

3. The oscillator according to claim 2, wherein:
the amplifying elements are fabricated on a silicon substrate and are associated in series, firstly via a first group of transmission line sections made in a first metal level located above the substrate, and secondly via a second group of transmission line sections made in a second-to-last metal level located above the first level,
the first transmission line and the second transmission line are made in the second-to-last metal level,
the second transmission line is formed parallel to the first transmission line.

4. The oscillator according to claim 2, wherein:
the amplifying elements are fabricated on a silicon substrate and are associated in series, firstly via a first group of transmission line sections made in a first metal level located above the substrate, and secondly via a second group of transmission line sections made in a last metal level located above the first metal level,
the first transmission line and the second transmission line are made in the last metal level,
the second transmission line is formed parallel to the first transmission line.

5. The oscillator according to claim 1, wherein the first transmission line and/or the second transmission line are microstrip lines with DGS structure.

6. The oscillator according to claim 1, wherein the amplifying elements are:
transistors of either a bipolar or MOS type.

7. The oscillator according to claim 1, wherein the amplifying elements are distributed so that the transmission line sections and the first transmission line are substantially of same length.

8. The oscillator according to claim 7, comprising three amplifying elements distributed in a substantially triangular architecture.

9. A circuit, comprising:
an oscillator comprising:
a plurality of amplifying elements coupled in series; and
a first transmission line coupled between an output of a last one of the amplifying elements and an input of a first one of the amplifying elements;
a control circuit adapted to generate an oscillating control signal; and
a second transmission line receiving the oscillating control signal from the control circuit at an input and arranged with the first transmission line to form an electromagnetic directional coupler.

10. The circuit of claim 9 wherein the oscillating control signal has a control frequency f2 and the oscillator has an output frequency f1=n*f2.

11. The circuit of claim 10 wherein n is an integer from 2 to 10.

12. The circuit of claim 9 further comprising a terminating impedance connected to an output of the second transmission line.

13. The circuit of claim 9 wherein the first and second transmission lines are fabricated adjacent to each other and having a parallel orientation.

14. The circuit of claim 9, wherein the first and second transmission lines each comprise a microstrip line having a DGS structure.

15. The circuit of claim 9 wherein the amplifying elements are interconnected by additional third and fourth transmission lines, the first through fourth transmission lines all having substantially a same length.

16. A circuit, comprising:
a semiconductor substrate;
a first transistor, second transistor and third transistor formed on the substrate and positioned at the corners of a triangle;
a first transmission line coupled between the first and second transistors;
a second transmission line coupled between the second and third transistors;
a third transmission line coupled between the third and first transistors; and
a fourth transmission line positioned adjacent and parallel to the third transmission line to form with the third transmission line an electromagnetic directional coupler.

17. The circuit of claim 16 wherein the first and second transmission lines are formed in a first metallization level located above the substrate, the third transmission line is formed in a second metallization level located above the first metallization level, and the fourth transmission line is formed in a third metallization level located above the second metallization level.

18. The circuit of claim 16 further comprising a control circuit adapted to generate an oscillating control signal for application to an input of the fourth transmission line, the first through third transistors interconnected by the first through third transmission lines forming an oscillator operating at a frequency controlled by the oscillating control signal.

19. The circuit of claim 18 wherein the oscillating control signal has a control frequency f2 and the oscillator has an operating frequency f1=n*f2.

20. The circuit of claim 16 wherein the first through fourth transmission lines have substantially a same length.
